(19) United States
(12) Patent Application Publication
(10) Pub. No.: US 2007/0201209 A1
(43) Pub. Date: Aug. 30, 2007

(54) CONNECTION APPARATUS AND METHOD

(76) Inventors: Sally Jean Francis, Fairfax, VT (US); William Lee Hammond, Colchester, VT (US); Daniel A. Piaseczny, Westford, VT (US); Mohammed Siddique Shaikh, Essex Junction, VT (US)

Correspondence Address: SCHMEISER, OLSEN & WATTS, 22 CENTURY HILL DRIVE, SUITE 302, LATHAM, NY, 12110, US

(21) Appl. No.: 11/276,361

(22) Filed: Feb. 27, 2006

(51) Int. Cl. H05K 7/20

(52) U.S. Cl. 361/704

(57) ABSTRACT

A connection apparatus and associated method. The apparatus comprises a space transformer assembly and a leveling apparatus. The space transformer is adapted to electrically connect a testing apparatus to a semiconductor device through an interface board. The leveling apparatus is adapted to apply varying amounts of force to a plurality of sections of the interface substrate. The varying amounts of force are adapted to generate pressure on the plurality of sections of the interface substrate and form electrical connections between contacts on the interface substrate and all contacts on the semiconductor device.

### BACKGROUND OF THE INVENTION

1. Technical Field

The present invention relates to an apparatus and method to electrically connect a semiconductor device to an apparatus for testing the semiconductor device.

2. Related Art

Apparatuses used to establish electrical connections between electrical devices typically do not account for structural or placement differences between the electrical devices. Such apparatuses may result in electrical connections that are unreliable. Thus there is a need for an apparatus and method for establishing reliable electrical connections between electrical devices comprising structural or placement differences.

### SUMMARY OF THE INVENTION

The present invention provides an apparatus, comprising:

a space transformer assembly comprising a printed circuit board (PCB) including an interface portion, a pressure plate assembly located over and in contact with a top surface of said interface portion, and an interface substrate located below a bottom surface of said interface portion, wherein said space transformer is adapted to electrically connect a testing apparatus to a semiconductor device, wherein said interface substrate comprises electrically conductive members extending through said interface substrate from a first side to a second side of said interface substrate, wherein said pressure plate assembly secures said interface substrate to said bottom surface of said interface portion such that electrical connections between contact pads within said bottom surface of said interface portion and a first surface of said electrically conductive members are formed, and wherein said interface substrate is adapted to electrically connect said contact pads within said bottom surface of said interface portion to said semiconductor device; and

a leveling apparatus located over said pressure plate assembly, wherein said semiconductor device comprises electrical contacts, wherein said leveling apparatus is adapted to apply varying amounts of force through said pressure plate assembly and said interface portion to a plurality of sections of said interface substrate, wherein said varying amounts of force are adapted to generate pressure on said plurality of sections of said interface substrate and form electrical connections between a second surface of each of said electrically conductive members and an associated contact of said contacts on said semiconductor device such that all of said contacts are electrically connected to said testing device, and wherein each of said varying amounts of force applied to said plurality of sections of said interface substrate is further adapted to level said interface substrate with respect to said pressure plate assembly such that said interface substrate is coplanar with said pressure plate assembly.

The present invention provides a method, comprising:

providing an apparatus comprising a space transformer assembly and a leveling apparatus, wherein said space transformer assembly comprises a printed circuit board (PCB) including an interface portion, a pressure plate assembly located over and in contact with a top surface of said interface portion, and an interface substrate located below a bottom surface of said interface portion, wherein said leveling apparatus is located over said pressure plate assembly, wherein said interface substrate comprises electrically conductive members extending through said interface substrate from a first side to a second side of said interface substrate, wherein said pressure plate assembly secures said interface substrate to said bottom surface of said interface portion such that electrical connections between contact pads within said bottom surface of said interface portion and a first surface of said electrically conductive members are formed, and wherein said leveling apparatus is located over said pressure plate assembly;

placing, said space transformer assembly, over a semiconductor device, wherein said semiconductor device comprises electrical contacts;

electrically connecting a testing apparatus to said space transformer assembly;

applying, by said leveling apparatus, varying amounts of force through said pressure plate assembly and said interface portion to a plurality of sections of said interface substrate;

leveling, by said each of said varying amounts of force, said interface substrate with respect to said pressure plate assembly such that said interface substrate is coplanar with said pressure plate assembly;

generating, by said varying amounts of force, pressure on said interface substrate; forming, by said pressure, electrical connections between a second surface of each of said electrically conductive members and an associated contact of said contacts on said semiconductor device such that all of said contacts are electrically connected to said interface substrate; and

electrically connecting, by said space transformer and said interface substrate, said testing apparatus to all of said contacts on said semiconductor device.

The present invention advantageously provides an apparatus and associated method for establishing reliable electrical connections between electrical devices comprising structural or placement differences.

### BRIEF DESCRIPTION OF THE DRAWINGS

FIG. 1 illustrates an exploded view of a system comprising an assembly and a testing apparatus, in accordance with embodiments of the present invention.

FIG. 2 illustrates a cross sectional view of the assembly of FIG. 1, in accordance with embodiments of the present invention.

FIG. 3 illustrates an alternative embodiment to FIG. 2, in accordance with embodiments of the present invention.

FIG. 4 illustrates a first alternative to the leveling apparatus of FIG. 1, in accordance with embodiments of the present invention.

FIG. 5 illustrates a second alternative to the leveling apparatus of FIG. 1, in accordance with embodiments of the present invention.

FIG. 6 illustrates a cross sectional view of the leveling apparatus of FIG. 5, in accordance with embodiments of the present invention.

FIG. 7 illustrates a third alternative to the leveling apparatus of FIG. 1, in accordance with embodiments of the present invention.

FIG. 8 illustrates a cross sectional view of the leveling apparatus of FIG. 7, in accordance with embodiments of the present invention.

FIG. 9 illustrates a fourth alternative to the leveling apparatus of FIG. 1, in accordance with embodiments of the present invention.

FIG. 10 illustrates a cross sectional view of the leveling apparatus of FIG. 9, in accordance with embodiments of the present invention.

### DETAILED DESCRIPTION OF THE INVENTION

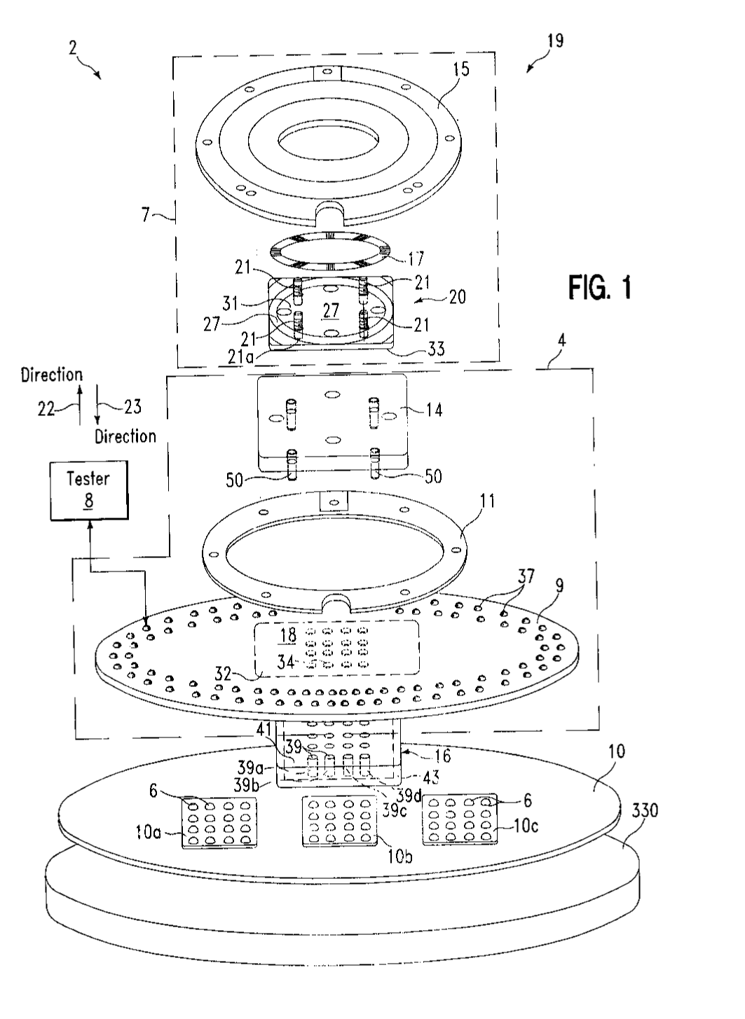

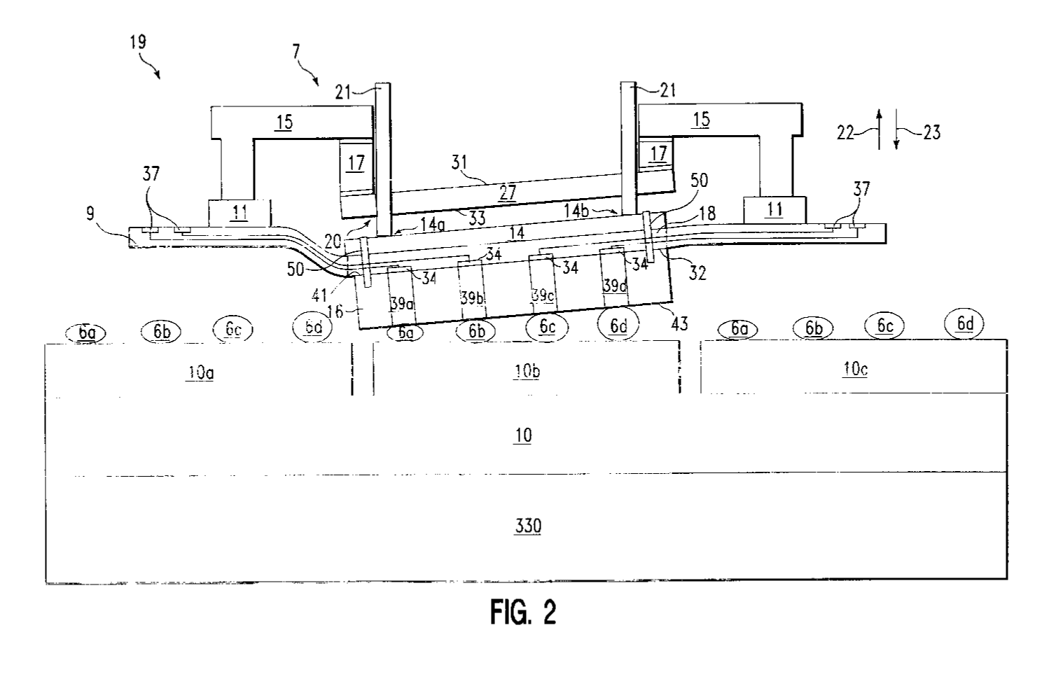

FIG. 1 illustrates an exploded view of a system 2 comprising an assembly 19 and a testing apparatus 8, in accordance with embodiments of the present invention. The assembly 19 comprises a space transformer assembly 4, a leveling apparatus 7 and a semiconductor wafer 10 on a stepping stage 330. The stepping stage 330 comprises a platform for the semiconductor wafer 10. The space transformer assembly 4 comprises a printed circuit board (PCB) 9, a frame 11, a pressure plate assembly 14, and an interface substrate 16. The frame 11 is secured to the PCB 9. The PCB 9 comprises an interface portion 18 located within a center portion of the PCB 9. A bottom surface 32 of the interface portion 18 comprises electrical contacts 34 (see FIG. 2) that are electrically connected to electrical contacts 37 on the PCB 9. The electrical contacts 37 are used to electrically connect the test apparatus 8 to the PCB 9 thereby electrically connecting the test apparatus 8 to the electrical contacts 34. The space transformer assembly 4 is used to electrically connect the testing apparatus 8 to each of the semiconductor devices 10a . . . 10c on the semiconductor wafer 10 in order to test (e.g., test for functionality, test for malfunctions, etc) each of the semiconductor devices 10a . . . 10c. The interface substrate 16 comprises through-hole electrical contacts 39 (i.e., including contacts 39a . . . 39d). Each through-hole electrical contact 39 comprises an electrically conductive contact that extends through the interface substrate 16 from a top side 41 to a bottom side 43 of the interface substrate 16. The through-hole electrical contacts 39 electrically connect the contacts 34 on the interface portion 18 to electrical contacts 6 on each of the semiconductor devices 10a . . . 10c (i.e., each of semiconductor devices 10a . . . 10c is electrically connected to the contacts 34 at a different time). The electrical contacts 6 may comprise, inter alia, controlled collapse solder ball (C4) connections. The pressure plate assembly 14 secures the interface substrate 16 to the interface portion 18 such that the electrical contacts 34 are electrically connected to the through-hole electrical contacts 39. The pressure plate assembly 14 may comprise fasteners 50 (e.g., screws, rivets, etc) that extend through pressure plate assembly 14, the PCB 9, and the interface substrate 16. The fasteners 50 secure the interface substrate 16 such that the interface portion 18 is sandwiched between the pressure plate assembly 14 and the interface substrate 16.

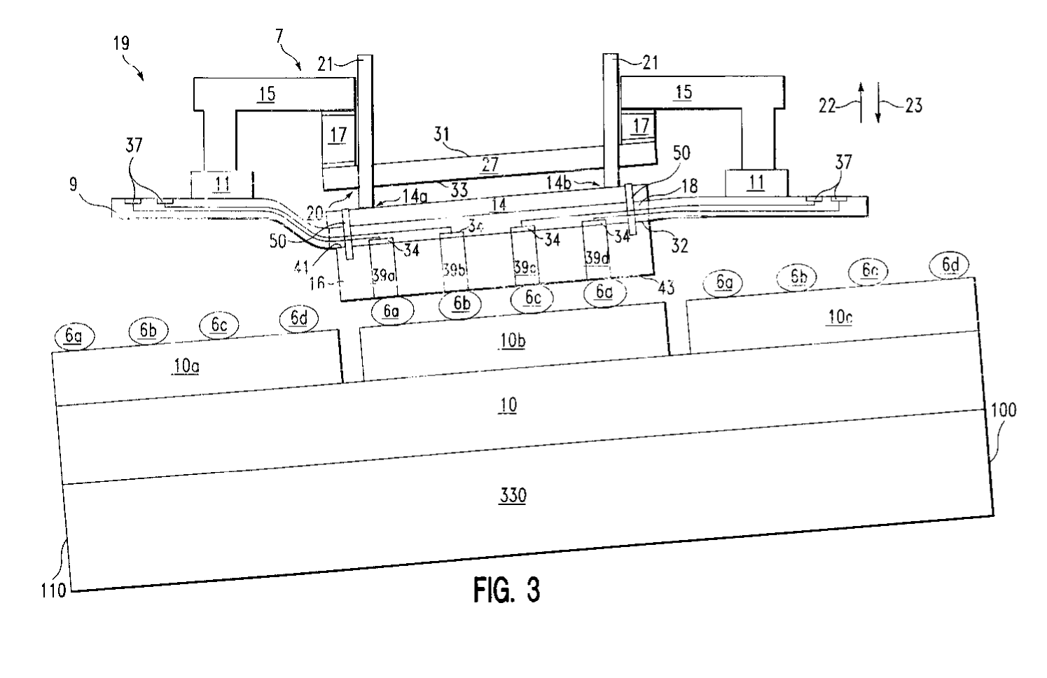

The leveling apparatus 7 comprises a housing assembly 15, a spring assembly 17, and an adjustment mechanism 20. The spring assembly may comprise a single spring as shown in FIG. 1 or a plurality of springs as shown in FIG. 3, supra. Each of the housing assembly 15, the spring assembly 17, and the adjustment mechanism 20 may independently comprise any material including, inter alia, metal, plastic, etc. The spring assembly 17 may comprise any type of spring known to a person of ordinary skill in the art including, inter alia, a coil spring, a torsion spring, a wave spring, etc. The adjustment mechanism 20 in FIG. 1 comprises a rigid plate 27 and a plurality of set screws 21 extending through the rigid plate 27 (i.e., the plurality of set screws 21 extending through threaded holes within the rigid plate 27) from a top side 31 through a bottom side 33 of the rigid plate 27. The housing assembly 15 is located over the spring assembly 17 and the spring assembly 17 is located over the adjustment mechanism 20. The adjustment mechanism 20 is located over the plate 14. The housing assembly 15 is secured to the frame 11 (i.e., as shown in FIG. 2). The spring assembly 17 and the adjustment mechanism 20 ‘float’ (i.e., not secured to anything) between the housing assembly 15 and the plate 14 (i.e., as shown in FIG. 2). Each of the set screws 21 is adapted to be rotated such that a bottom surface 21a of each set screw 21 extends in a direction 23 while the rigid plate 27 moves in a direction 22. Each of the set screws 21 in combination with the spring assembly 17 will exert a force that will form electrical connections between contacts 39 on the interface substrate 16 (i.e., all of the contacts 39 on the interface substrate 16) and contacts 6 on each semiconductor device 10a . . . 10c (i.e., all of the contacts 6 on each semiconductor device 10a . . . 10c). Additionally, each of the set screws 21 in combination with the spring assembly 17 will exert a force that will level the interface substrate 16 with respect to the pressure plate assembly 14 such that the interface substrate 16 is coplanar with the pressure plate assembly 14. The above mentioned process results in generating electrical connections between all of contacts 6 and all of contacts 39 in a situation where some of contacts 6 comprise a different size from each other and as a result the semiconductor device 10a . . . 10c that is being tested is not coplanar with the interface substrate 16 as described in detail with respect to FIG. 2. Alternatively, the above mentioned process results in generating electrical connections between all of contacts 6 (i.e., all of contacts 6 comprise a same size) and all of contacts 39 in a situation where the stepping stage 330 and/or the semiconductor wafer 10 is tilted with respect to the direction 22 and 23 as described with respect to FIG. 3.

FIG. 2 illustrates a cross sectional view of the assembly 19 of FIG. 1, in accordance with embodiments of the present invention. The cross sectional view of FIG. 2 represents a cross section view of an assembled version of the assembly 19 of FIG. 1 (i.e., all of the components in the exploded view of assembly 19 of FIG. 1 have been assembled in their respective positions in the cross sectional view of FIG. 2). The contacts 6a-6d in FIG. 2 represents a set of the contacts 6 from FIG. 1. Each of the contacts 6a . . . 6d in FIG. 2 comprises a different size (e.g., each of the contacts 6a . . . 6d in FIG. 2 may comprises a different height). The leveling apparatus 7 positions the interface substrate 16 in such a way that will enable and maintain electrical connections between contacts 6a . . . 6d of different sizes and contacts 39a . . . 39d). The contacts 39a-39d in FIG. 2 represents a set of the contacts 39 from FIG. 1. In FIG. 2, each of the set screws 21 have been rotated such that a bottom surface 21a of each set screw 21 extends in a direction 23 causing a first portion 14a of the pressure plate assembly 14 to move in a direction 22 and a second portion 14b of the pressure plate assembly 14 to move in a direction 22 (i.e., the pressure plate assembly 14 becomes tilted). The pressure plate assembly 14 tilting begins to compress the spring assembly 17 causing the spring assembly 17 to exert a force in the direction 23 on the rigid plate 27. The aforementioned process causes the each of the set screws 21 to apply varying amounts of force to the pressure plate assembly 14, the interface portion 18, (i.e., through the plate 14), and the interface substrate 16 (i.e., through the interface portion 18). Each amount of force applied by each of the set screws 21 is adjustable (i.e., by rotating each of the set screws 21). Each amount of force applied by each of the set screws 21 is dependent upon a distance that the bottom surface 21a of each set screw 21 extends from the bottom surface of the rigid plate and an amount of force exerted by the spring assembly 17. Each of the set screws 21 is rotated to exert a specified amount of force that will tilt the pressure plate assembly 14 and cause the interface portion 18 to flex. The above mentioned process will cause the interface substrate 16 to tilt in such a way that each of the through-hole electrical contacts 39a . . . 39d is electrically connected to an associated contact 6a . . . 6d (i.e., of different sizes) on the semiconductor device 10b. As a result, each of the set screws 21 in combination with the spring assembly 17 will level the interface substrate 16 with respect to the pressure plate assembly 14 such that the interface substrate 16 is coplanar with the pressure plate assembly 14 and consequently the semiconductor device 10b that is being tested will not be not coplanar with the interface substrate 18. The resulting structure (i.e., assembly 19) will enable electrical connections between the through-hole electrical contacts 39a . . . 39d and the different sized contacts 6a . . . 6d (i.e., on the semiconductor device 10b).

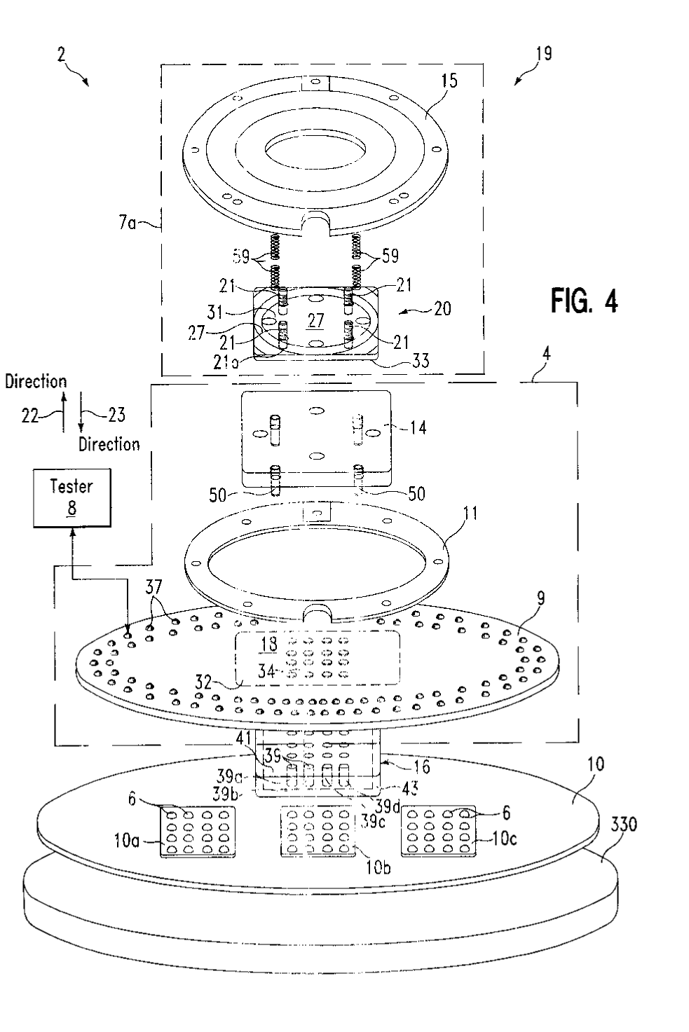

FIG. 3 illustrates an alternative embodiment to FIG. 2, in accordance with embodiments of the present invention. In contrast with FIG. 2, FIG. 3 illustrates a situation where all of the 6a . . . 6d (i.e., all of contacts 6) on semiconductor devices 10a . . . 10c comprise a same size. Additionally, FIG. 3 illustrates a situation where the stepping stage 330 is tilted such that a first side of the stepping stage 330 has moved in the direction 22 and a second side of the stepping stage 330 has moved in the direction 23. In the aforementioned situation, the leveling apparatus 7 positions (i.e., tilts) the interface substrate 16 in such a way that will enable and maintain electrical connections between all of contacts 6 and all of contacts 39 when the stepping stage 330 is tilted. Therefore, the interface substrate 16 will be coplanar with the stepping stage 330. Note that all embodiments described with reference to FIGS. 4-10, infra, may be implemented to enable connections between all of contacts 6 (i.e., comprising a same size) on semiconductor devices 10a . . . 10c in a situation where the stepping stage 330 and/or the semiconductor wafer 10 is tilted.

FIG. 4 illustrates a first alternative to the leveling apparatus 7 of FIG. 1, in accordance with embodiments of the present invention. In contrast to the leveling apparatus 7 of FIG. 1, the leveling apparatus 7a of FIG. 4 comprises a plurality of springs 59. Each of the set screws 21 in combination with the springs 59 will exert a force that will form electrical connections between contacts 39 on the interface substrate 16 and contacts 6 on each semiconductor device 10a . . . 10c (i.e., as described with respect to the spring 17 in FIG. 1). Each of springs 59 may comprise any type of spring known to a person of ordinary skill in the art including, inter alia, a coil spring, a torsion spring, a wave spring, etc.

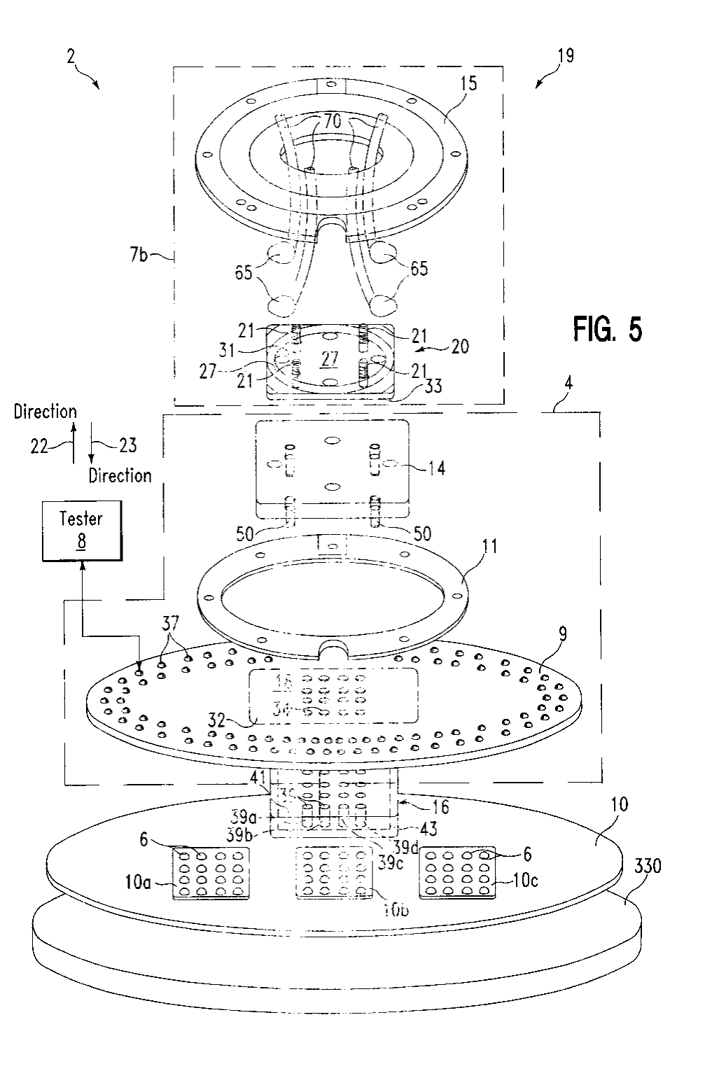

FIG. 5 illustrates a second alternative to the leveling apparatus 7 of FIG. 1, in accordance with embodiments of the present invention. In contrast to the leveling apparatus 7 of FIG. 1, the leveling apparatus 7b of FIG. 5 comprises bladder assemblies 65 instead the spring assembly 17 in FIG. 1. The bladder assemblies 65 of FIG. 5 perform the same functions as the spring assembly 17 of FIG. 1. Each of the bladder assemblies 65 is pressurized with a fluid (e.g., a gas, a liquid, etc) such that each of the bladder assemblies 65 in combination with the set screws 21 will exert a force that will form electrical connections between contacts 39 on the interface substrate 16 and contacts 6 on each semiconductor device 10a . . . 10c. Each of the bladder assemblies 65 may comprise a tube 70 for connecting to a fluid source and transferring a fluid to the bladder assemblies 65.

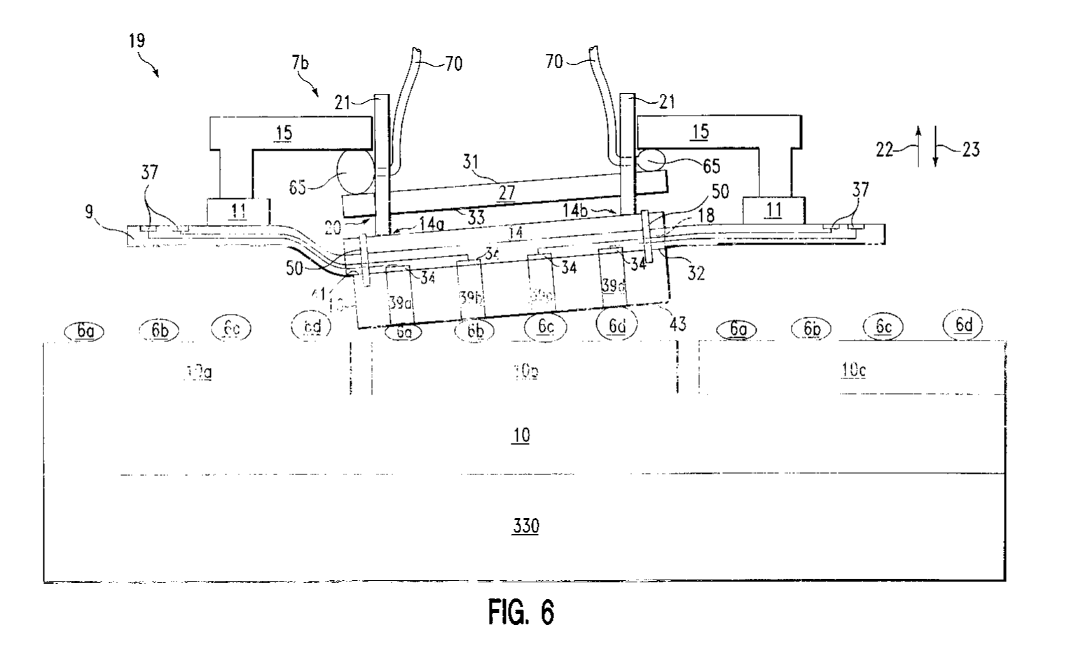

FIG. 6 illustrates a cross sectional view of the leveling apparatus 7b of FIG. 5 (i.e., within apparatus 19), in accordance with embodiments of the present invention. The cross sectional view of FIG. 6 represents a cross sectional view of an assembled version of the assembly 19 of FIG. 5 (i.e., all of the components in the exploded view of assembly 19 of FIG. 5 have been assembled in their respective positions in the cross sectional view of FIG. 6). Each of the bladder assemblies 65 is pressurized with a fluid (e.g., a gas, a liquid, etc) such that each of the bladder assemblies 65 expand. The aforementioned process causes the each of the pressurized bladder assemblies 65 in combination with the set screws 21 to apply varying amounts of force to the plate 14, the interface portion 18, (i.e., through the plate 14), and the interface substrate 16 (i.e., through the interface portion 18). A force exerted by each pressurized bladder assembly 65 is adjustable (i.e., by pressurizing the pressurized bladder assemblies 65 with a different amount of fluid). Each of the bladder assemblies 65 is pressurized to exert a specified amount of force that will in combination with the set screws 21 tilt the pressure plate assembly 14 and cause the interface portion 18 to flex. The above mentioned process will cause the interface substrate 16 to tilt in such a way that each of the through-hole electrical contacts 39a . . . 39d is electrically connected to an associated contact 6a . . . 6d (i.e., of different sizes) on the semiconductor device 10b. As a result, each of the pressurized bladder assemblies 65 in combination with the set screws 21 will level the interface substrate 16 with respect to the pressure plate assembly 14 such that the interface substrate 16 is coplanar with the pressure plate assembly 14 and consequently the semiconductor device 10b that is being tested will not be not coplanar with the interface substrate 18. The resulting structure (i.e., leveling apparatus 7b in assembly 19) will enable electrical connections between the through-hole electrical contacts 39a . . . 39d and the different sized contacts 6a . . . 6d (i.e., on the semiconductor device 10b).

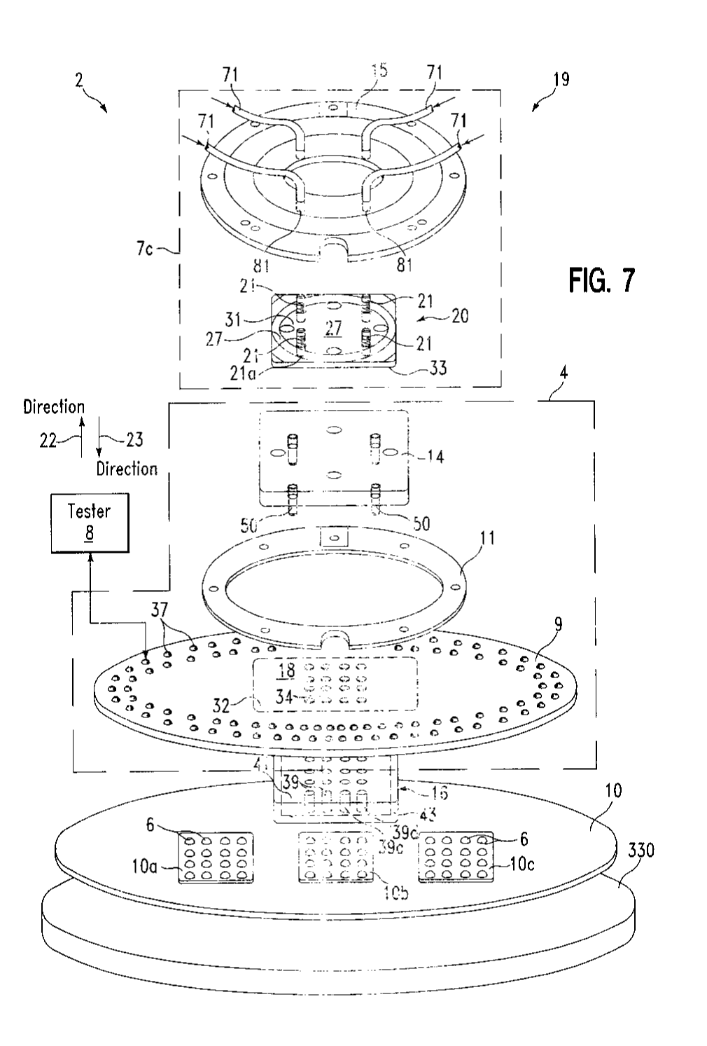

FIG. 7 illustrates a third alternative to the leveling apparatus 7 of FIG. 1, in accordance with embodiments of the present invention. In contrast to the leveling apparatus 7 of FIG. 1, the leveling apparatus 7c of FIG. 7 comprises tubes 71 (or pressurized lines) instead of the spring assembly 17 in FIG. 1. The tubes 71 of FIG. 7 perform the same functions as of the spring assembly 17 of FIG. 1. Each of the tubes 71 is adapted to emit a stream of pressurized gas (e.g., oxygen, nitrogen, etc) at different pressures or flows in direction 23 such that each flow of pressurized gas in combination the set screws 21 will exert a force that will form electrical connections between contacts 39 on the interface substrate 16 and contacts 6 on each semiconductor device 10a . . . 10c. The pressurized gas for each of the tubes 71 may be supplied by an external tank or compressor. Each tube 71 may comprise an adjustable nozzle 81 for regulating a flow of the pressurized gas.

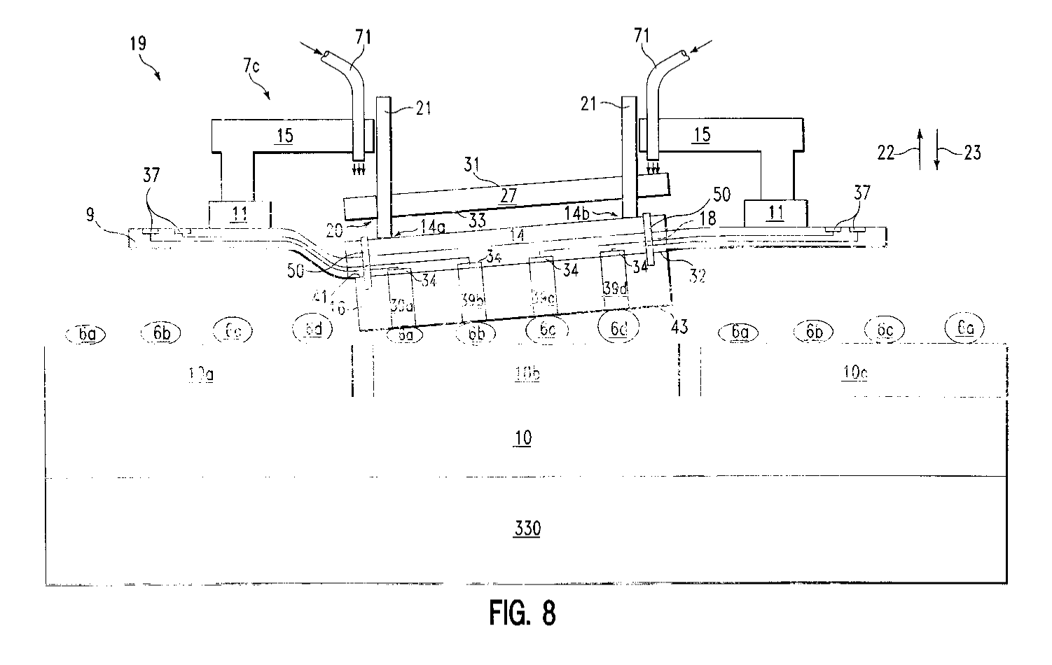

FIG. 8 illustrates a cross sectional view of the leveling apparatus 7c of FIG. 7 (i.e., within apparatus 19), in accordance with embodiments of the present invention. The cross sectional view of FIG. 8 represents a cross sectional view of an assembled version of the assembly 19 of FIG. 7 (i.e., all of the components in the exploded view of assembly 19 of FIG. 7 have been assembled in their respective positions in the cross sectional view of FIG. 8). Each of the tubes 71 is adapted to emit a stream of pressurized gas (e.g., oxygen, nitrogen, etc) in direction 23 at different pressures or flow rates. The aforementioned process causes the each of the flows of pressurized gas in combination with the set screws 21 to apply varying amounts of force to the plate 14, the interface portion 18, (i.e., through the plate 14), and the interface substrate 16 (i.e., through the interface portion 18). Each amount of flow of pressurized gas applied by each of the tubes 71 is adjustable (i.e., by increasing or decreasing a flow). Each amount of flow of pressurized gas applied by each of the tubes 71 is adjusted to emit a specified flow of gas that will in combination with the set screws 21 tilt the pressure plate assembly 14 and cause the interface portion 18 to flex. The above mentioned process will cause the interface substrate 16 to tilt in such a way that each of the through-hole electrical contacts 39a . . . 39d is electrically connected to an associated contact 6a . . . 6d (i.e., of different sizes) on the semiconductor device 10b. As a result, each of the tubes 71 emitting each specified flow of gas combination with the set screws 21 will level the interface substrate 16 with respect to the pressure plate assembly 14 such that the interface substrate 16 is coplanar with the pressure plate assembly 14 and consequently the semiconductor device 10b that is being tested will not be not coplanar with the interface substrate 18. The resulting structure (i.e., leveling apparatus 7c in assembly 19) will enable electrical connections between the through-hole electrical contacts 39a . . . 39d and the different sized contacts 6a . . . 6d (i.e., on the semiconductor device 10b).

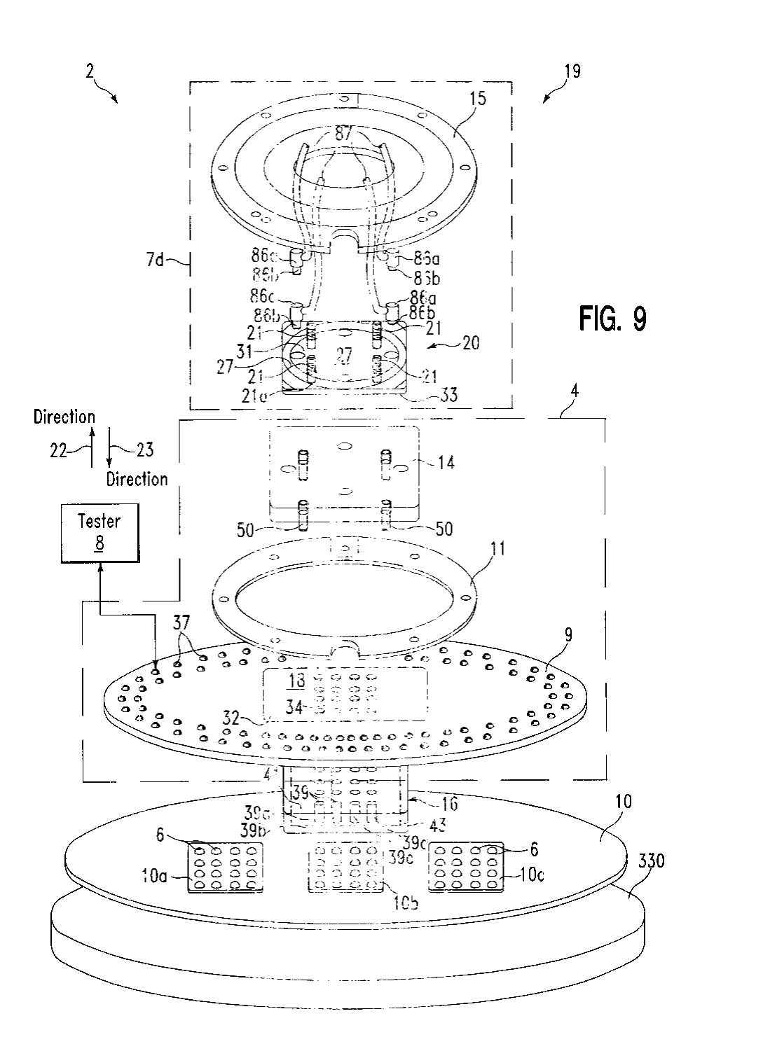

FIG. 9 illustrates a fourth alternative to the leveling apparatus 7 of FIG. 1, in accordance with embodiments of the present invention. In contrast to the leveling apparatus 7 of FIG. 1, the leveling apparatus 7d of FIG. 9 comprises plunger assemblies 86 instead the spring assembly 17 in FIG. 1. The plunger assemblies 86 of FIG. 9 perform the same functions as the spring assembly 17 of FIG. 1. Each plunger assembly 86 comprises a cylinder 86a, a plunger (or piston) 86b, and a connection/input tube 87. The cylinder 86a is pressurized with a fluid (e.g., a gas or a liquid) that causes the plunger 86b to move and exert a force in direction 23. Therefore, each plunger assembly 86 in combination with the set screws 21 will exert a force that will form electrical connections between contacts 39 on the interface substrate 16 and contacts 6 on each semiconductor device 10a . . . 10c. Each plunger assembly 86 comprises a connection/input tube for connecting to a fluid source and transferring a fluid to the plunger assembly 86.

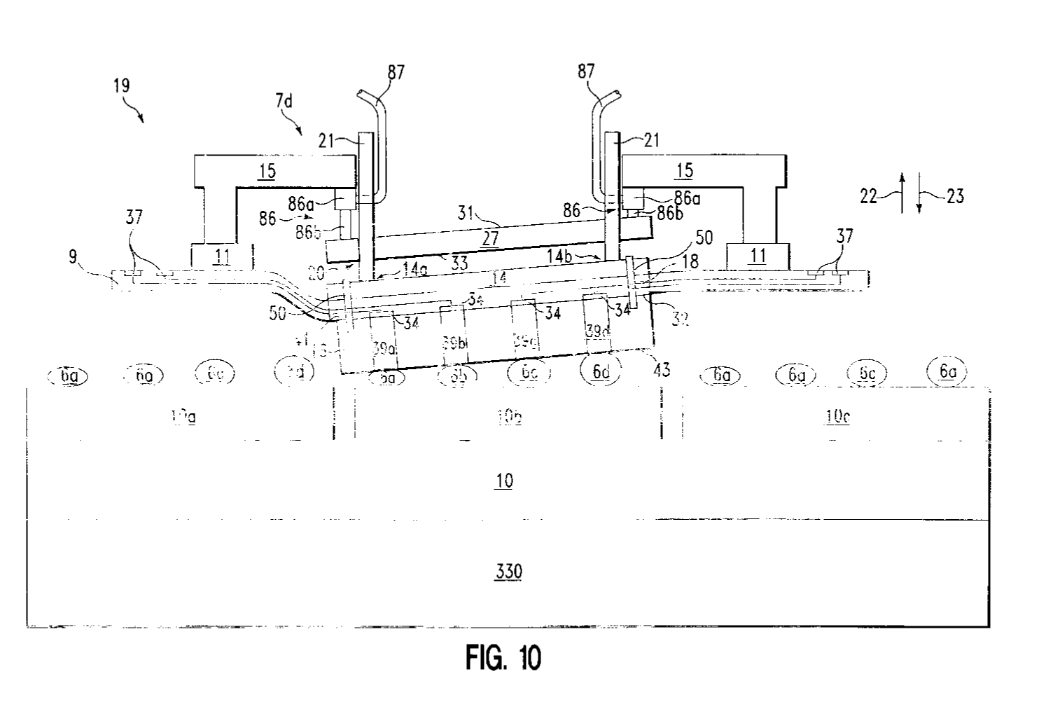

FIG. 10 illustrates a cross sectional view of the leveling apparatus 7d of FIG. 9 (i.e., within apparatus 19), in accordance with embodiments of the present invention. The cross sectional view of FIG. 10 represents a cross sectional view of an assembled version of the assembly 19 of FIG. 9 (i.e., all of the components in the exploded view of assembly 19 of FIG. 9 have been assembled in their respective positions in the cross sectional view of FIG. 10). Each plunger assembly 86 is pressurized with a fluid (e.g., a gas, a liquid, etc) such that each of the plungers 86b exert a force in direction 23. The aforementioned process causes the each plunger assembly 86 in combination with the set screws 21 to apply varying amounts of force to the plate 14, the interface portion 18, (i.e., through the plate 14), and the interface substrate 16 (i.e., through the interface portion 18). A force exerted by each plunger 86b is adjustable (i.e., by pressurizing each plunger assembly 86 with a different amount of fluid). Each plunger assembly 86 is pressurized to exert a specified amount of force that will in combination with the set screws 21 tilt the pressure plate assembly 14 and cause the interface portion 18 to flex. The above mentioned process will cause the interface substrate 16 to tilt in such a way that each of the through-hole electrical contacts 39a . . . 39d is electrically connected to an associated contact 6a . . . 6d (i.e., of different sizes) on the semiconductor device 10b. As a result, each of the pressurized bladder assemblies 65 in combination with the spring assembly 17 will level the interface substrate 16 with respect to the pressure plate assembly 14 such that the interface substrate 16 is coplanar with the pressure plate assembly 14 and consequently the semiconductor device 10b that is being tested will not be not coplanar with the interface substrate 18. The resulting structure (i.e., leveling apparatus 7b in assembly 19) will enable electrical connections between the through-hole electrical contacts 39a . . . 39d and the different sized contacts 6a . . . 6d (i.e., on the semiconductor device 10b).

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. An apparatus, comprising:
a space transformer assembly comprising a printed circuit board (PCB) including an interface portion, a pressure plate assembly located over and in contact with a top surface of said interface portion, and an interface substrate located below a bottom surface of said interface portion, wherein said space transformer is adapted to electrically connect a testing apparatus to a semiconductor device, wherein said interface substrate comprises electrically conductive members extending through said interface substrate from a first side to a second side of said interface substrate, wherein said pressure plate assembly secures said interface substrate to said bottom surface of said interface portion such that electrical connections between contact pads within said bottom surface of said interface portion and a first surface of said electrically conductive members are formed, and wherein said interface substrate is adapted to electrically connect said contact pads within said bottom surface of said interface portion to said semiconductor device; and
a leveling apparatus located over said pressure plate assembly, wherein said semiconductor device comprises electrical contacts, wherein said leveling apparatus is adapted to apply varying amounts of force through said pressure plate assembly and said interface portion to a plurality of sections of said interface substrate, wherein said varying amounts of force are adapted to generate pressure on said plurality of sections of said interface substrate and form electrical connections between a second surface of each of said electrically conductive members and an associated contact of said contacts on said semiconductor device such that all of said contacts are electrically connected to said testing device, and wherein each of said varying amounts of force applied to said plurality of sections of said interface substrate is further adapted to level said interface substrate with respect to said pressure plate assembly such that said interface substrate is coplanar with said pressure plate assembly.

2. The apparatus of claim 1, wherein said leveling apparatus comprises an adjustment mechanism, a spring assembly, and a housing fixture, wherein said adjustment mechanism is located over said pressure plate assembly, wherein said spring assembly is located over and in contact with said adjustment mechanism, wherein said housing fixture is located over said spring assembly and said adjustment mechanism, wherein said adjustment mechanism comprises adjustment devices, and wherein each of said adjustment devices in combination with said spring assembly is adapted to apply each of said varying amounts of force through said pressure plate assembly and said interface portion to said plurality of sections of said interface substrate.

3. The apparatus of claim 2, wherein each of said adjustment devices comprises a set screw threaded through said adjustment mechanism, and wherein each of said set screws is adapted to be rotated for adjusting each of said varying amounts of force through said pressure plate assembly and said interface portion to said plurality of sections of said interface substrate.

4. The apparatus of claim 2, wherein said spring assembly comprises an assembly selected from the group consisting of a single spring and a plurality of springs.

5. The apparatus of claim 1, wherein said leveling apparatus comprises an adjustment mechanism, a plurality of pressurized bladders, and a housing fixture, wherein said adjustment mechanism is located over said pressure plate assembly, wherein said plurality of pressurized bladders are located over and in contact with said adjustment mechanism, wherein said housing fixture is located over said plurality of pressurized bladders and said adjustment mechanism, wherein said adjustment mechanism comprises adjustment devices, and wherein each of said adjustment devices in combination with said plurality of pressurized bladders is adapted to apply each of said varying amounts of force through said pressure plate assembly and said interface portion to said plurality of sections of said interface substrate.

6. The apparatus of claim 5, wherein each of said adjustment devices comprises a set screw threaded through said adjustment mechanism, and wherein each of said set screws is adapted to be rotated for adjusting each of said varying amounts of force through said pressure plate assembly and said interface portion to said plurality of sections of said interface substrate.

7. The apparatus of claim 1, wherein said leveling apparatus comprises an adjustment mechanism, a housing fixture, and pressurized lines mechanically attached to said housing fixture, wherein said adjustment mechanism is located over said pressure plate assembly, wherein said housing fixture is located over said adjustment mechanism, wherein said pressurized lines extend through said housing fixture such that each of said pressurized lines are adapted to emit a stream of pressurized gas on said adjustment mechanism, wherein said adjustment mechanism comprises adjustment devices, and wherein each of said adjustment devices in combination with each of said pressurized lines is adapted to apply each of said varying amounts of force through said pressure plate assembly and said interface portion to said plurality of sections of said interface substrate.

8. The apparatus of claim 7, wherein each of said adjustment devices comprises a set screw threaded through said adjustment mechanism, and wherein each of said set screws is adapted to be rotated for adjusting each of said varying amounts of force through said pressure plate assembly and said interface portion to said plurality of sections of said interface substrate.

9. The apparatus of claim 1, wherein said leveling apparatus comprises an adjustment mechanism, a housing fixture, and pressurized plunger assemblies mechanically attached to said housing fixture, wherein said adjustment mechanism is located over said pressure plate assembly, wherein said housing fixture is located over said adjustment mechanism, wherein said pressurized plunger assemblies are mechanically attached to said housing fixture, wherein each of said pressurized plunger assemblies comprises a plunger device adapted to apply pressure to said adjustment mechanism, wherein said adjustment mechanism comprises adjustment devices, and wherein each of said adjustment devices in combination with each of said pressurized plunger assemblies is adapted to apply each of said varying amounts of force through said pressure plate assembly and said interface portion to said plurality of sections of said interface substrate.

10. The apparatus of claim 9, wherein each of said adjustment devices comprises a set screw threaded through said adjustment mechanism, and wherein each of said set screws is adapted to be rotated for adjusting each of said varying amounts of force through said pressure plate assembly and said interface portion to said plurality of sections of said interface substrate.

11. A method, comprising:
providing an apparatus comprising a space transformer assembly and a leveling apparatus, wherein said space transformer assembly comprises a printed circuit board (PCB) including an interface portion, a pressure plate assembly located over and in contact with a top surface of said interface portion, and an interface substrate located below a bottom surface of said interface portion, wherein said leveling apparatus is located over said pressure plate assembly, wherein said interface substrate comprises electrically conductive members extending through said interface substrate from a first side to a second side of said interface substrate, wherein said pressure plate assembly secures said interface substrate to said bottom surface of said interface portion such that electrical connections between contact pads within said bottom surface of said interface portion and a first surface of said electrically conductive members are formed, and wherein said leveling apparatus is located over said pressure plate assembly;
placing, said space transformer assembly, over a semiconductor device, wherein said semiconductor device comprises electrical contacts;
electrically connecting a testing apparatus to said space transformer assembly;
applying, by said leveling apparatus, varying amounts of force through said pressure plate assembly and said interface portion to a plurality of sections of said interface substrate;
leveling, by said each of said varying amounts of force, said interface substrate with respect to said pressure plate assembly such that said interface substrate is coplanar with said pressure plate assembly;
generating, by said varying amounts of force, pressure on said interface substrate; forming, by said pressure, electrical connections between a second surface of each of said electrically conductive members and an associated contact of said contacts on said semiconductor device such that all of said contacts are electrically connected to said interface substrate; and
electrically connecting, by said space transformer and said interface substrate, said testing apparatus to all of said contacts on said semiconductor device.

12. The method of claim 11, wherein said leveling apparatus comprises an adjustment mechanism, a spring assembly, and a housing fixture, wherein said adjustment mechanism is located over said pressure plate assembly, wherein said spring assembly is located over and in contact with said adjustment mechanism, and wherein said housing fixture is located over said spring assembly and said adjustment mechanism, wherein said adjustment mechanism comprises adjustment devices, and wherein each of said adjustment devices in combination with said spring assembly perform said applying each of said varying amounts of force through said pressure plate assembly and said interface portion to said plurality of sections of said interface substrate.

13. The method of claim 12, wherein each of said adjustment devices comprises a set screw threaded through said adjustment mechanism, and wherein said method further comprises:
rotating each of said set screws to adjust each of said varying amounts of force through said pressure plate assembly and said interface portion to said plurality of sections of said interface substrate.

14. The method of claim 12, wherein said spring assembly comprises an assembly selected from the group consisting of a single spring and a plurality of springs.

15. The method of claim 11, wherein said leveling apparatus comprises an adjustment mechanism, a plurality of pressurized bladders, and a housing fixture, wherein said adjustment mechanism is located over said pressure plate assembly, wherein said plurality of pressurized bladders are located over and in contact with said adjustment mechanism, wherein said housing fixture is located over said plurality of pressurized bladders and said adjustment mechanism, wherein said adjustment mechanism comprises adjustment devices, and wherein each of said adjustment devices in combination with said plurality of pressurized bladders perform said applying each of said varying amounts of force through said pressure plate assembly and said interface portion to said plurality of sections of said interface substrate.

16. The method of claim 15, wherein each of said adjustment devices comprises a set screw threaded through said adjustment mechanism, and wherein said method further comprises:
rotating each of said set screws to adjust each of said varying amounts of force through said pressure plate assembly and said interface portion to said plurality of sections of said interface substrate.

17. The method of claim 11, wherein said leveling apparatus comprises an adjustment mechanism, a housing fixture, and pressurized lines mechanically attached to said housing fixture, wherein said adjustment mechanism is located over said pressure plate assembly, wherein said housing fixture is located over said adjustment mechanism, wherein said pressurized lines extend through said housing fixture such that each of said pressurized lines are adapted to emit a stream of pressurized gas on said adjustment mechanism, wherein said adjustment mechanism comprises adjustment devices, and wherein each of said adjustment devices in combination with each of said pressurized lines perform said applying each of said varying amounts of force through said pressure plate assembly and said interface portion to said plurality of sections of said interface substrate.

18. The method of claim 17, wherein each of said adjustment devices comprises a set screw threaded through said adjustment mechanism, and wherein said method further comprises:
rotating each of said set screws to adjust each of said varying amounts of force through said pressure plate assembly and said interface portion to said plurality of sections of said interface substrate.

19. The method of claim 11, wherein said leveling apparatus comprises an adjustment mechanism, a housing fixture, and pressurized plunger assemblies mechanically attached to said housing fixture, wherein said adjustment mechanism is located over said pressure plate assembly, wherein said housing fixture is located over said adjustment mechanism, wherein said pressurized plunger assemblies are mechanically attached to said housing fixture, wherein each of said pressurized plunger assemblies comprises a plunger device for applying pressure to said adjustment mechanism, wherein said adjustment mechanism comprises adjustment devices, and wherein each of said adjustment devices in combination with each of said pressurized plunger assemblies performs said applying each of said varying amounts of force through said pressure plate assembly and said interface portion to said plurality of sections of said interface substrate.

20. The method of claim 19, wherein each of said adjustment devices comprises a set screw threaded through said adjustment mechanism, and wherein said method further comprises:
rotating each of said set screws to adjust each of said varying amounts of force through said pressure plate assembly and said interface portion to said plurality of sections of said interface substrate.
